(19) United States
(12) Patent Application Publication
(10) Pub. No.: US 2018/0005826 A1
(43) Pub. Date: Jan. 4, 2018

(54) FORMING A SILICON BASED LAYER IN A TRENCH TO PREVENT CORNER ROUNDING

(71) Applicants: GLOBALFOUNDRIES Inc., Grand Cayman (KY); International Business Machines Corporation, Armonk, NY (US)

(72) Inventors: Ajey P. JACOB, Watervliet, NY (US); Jody FRONHEISER, Delmar, NY (US); Bruce DORIS, Slingerlands, NY (US); Huiming BU, Glenmont, NY (US)

(21) Appl. No.: 15/198,570

(22) Filed: Jun. 30, 2016

(51) Int. Cl. H01L 21/02; H01L 29/66; H01L 29/161; H01L 29/10; H01L 29/06; H01L 21/3065; H01L 29/78; H01L 29/165

(52) U.S. Cl. CPC H01L 21/02694; H01L 29/7851; H01L 29/66795; H01L 29/66537; H01L 29/165; H01L 21/0245; H01L 29/1054; H01L 29/0638; H01L 21/3065; H01L 21/02532; H01L 29/161

(57) ABSTRACT

A method of preventing corner rounding for an alternate channel FINFET formed in trenches and the resulting devices are provided. Embodiments include providing a Si substrate; forming a trench in the Si substrate; forming a Si based layer with a flat upper surface in the trench; and forming a SiGe layer over the Si based layer.

### TECHNICAL FIELD

The present disclosure relates to the manufacture of semiconductor devices, such as integrated circuits (ICs). The present disclosure is particularly applicable to forming alternate channel FIN field effect transistors (FINFETs), particularly for the 14 nanometer (nm) technology node and beyond.

### BACKGROUND

Conventional processes for the fabrication of semiconductor devices often incorporate a lithographic process to create a desired pattern on a Si substrate. As the critical dimensions of the desired pattern shrink, the consistency between the masked and actual layout pattern developed in the photoresist on the Si substrate is significantly reduced. Proximity effects in a lithographic process can arise during exposure, resist pattern formation and subsequent pattern transfer steps, such as etching. The proximity effect causes corner rounding, where substantially square corners of a pattern are rounded. Corner rounding generates many side effects, such as unexpected pattern shapes that may cause layout errors and device performance issues such as short-circuits, open-circuits, RC variation, and device performance drift, which in turn significantly impact device performance, quality and reliability.

For example, FIGS. 1A through 1C illustrate formation of a silicon germanium (SiGe) layer in a trench with round corners. FIG. 1A represents a Si substrate 101. Adverting to FIG. 1B, a trench 103 is formed in the Si substrate 101 by reactive ion etching (RIE) to a depth of 30 nanometer (nm) to 60 nm, for example 40 nm. Subsequent to etching, EPI pre-baking is performed on the surface of the trench 103 causing corner rounding. Then, in FIG. 1C, when a SiGe layer 105 (or more accurately, a Si₁₋ₓGeₓ layer, where x is between 0 and 1) is formed in the trench 103 for an alternate channel FINFET, the SiGe winds up with rounded corners. For example, SiGe layer 105 may be grown to a thickness that is greater than (e.g., overfill) or equal to (e.g., flush fill) the depth of the trench 103 to ensure that the trench 103 is filled to a minimum height that meets or exceeds the surface of the Si substrate 101. The overgrowth of the SiGe layer 105 may be smoothed to the level of the Si substrate 101 by chemical mechanical polishing (CMP). The portion where the corners are rounded, e.g. around area 107, cannot be used for patterning FINs. Therefore, corner rounding effectively causes FINs to be farther apart from one another. In an ideal situation the affected region could be greater than 25 nm, thereby rendering it difficult to form an optimized N/P ratio in a 14 nm technology node and beyond.

A need therefore exists for methodology enabling formation of a SiGe layer on silicon to form a SiGe FINFET transistor with no corner rounding and the resulting device.

### SUMMARY

An aspect of the present disclosure is a method including forming a Si based layer in a trench prior to forming a SiGe layer to prevent corner rounding for the SiGe layer.

Another aspect of the present disclosure is a device including a Si based layer with a flat upper surface under a SiGe layer in a trench to prevent corner rounding of the SiGe layer.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of including: providing a Si substrate; forming a trench in the Si substrate; forming a Si based layer with a flat upper surface in the trench; and forming a SiGe layer over the Si based layer.

Another aspect includes forming the trench by RIE. Further aspects include forming the Si based layer and the SiGe layer by epitaxially growing a lattice compliant Si layer and the SiGe layer in the trench. Other aspects include forming the Si based layer and the SiGe layer by epitaxially growing first and second SiGe layers, the first SiGe layer having a lower germanium (Ge) concentration than the second SiGe layer. Further aspects include forming the trench to a depth of 100 nm to 500 nm. Additional aspects include forming the Si based layer to a thickness equal to a difference between a depth of the trench and a thickness of the SiGe layer. Other aspects include forming the SiGe layer to a thickness of 10 nm to 60 nm. Further aspects include epitaxial (EPI) pre-baking surfaces of the trench subsequent to etching. Another aspect includes EPI pre-baking surfaces of the trench at a temperature of 750° C. to 1200° C. and a pressure of 10 torr to 600 torr for 1 minute to 5 minutes. A further aspect includes counter doping the lattice compliant Si layer with an n-type dopant.

A further aspect of the present disclosure is a device including: a Si substrate; a trench formed in the Si substrate; a Si based layer with a flat upper surface formed in the trench; and a SiGe layer with no corner rounding formed over the Si based layer.

Aspects include the Si based layer including a lattice compliant layer. Other aspects include the Si based layer including a second SiGe layer with a Ge concentration lower than the concentration of the SiGe layer. A further aspect includes the trench having a depth of 100 nm to 500 nm. Another aspect includes the Si based layer having a thickness equal to a difference between a depth of the trench and a thickness of the SiGe layer. A further aspect includes the SiGe layer having a thickness of 10 nm to 60 nm.

Another aspect of the present disclosure is a method including: providing a Si substrate; etching a trench to a depth of 100 nm to 500 nm in the Si substrate by RIE; epitaxially growing a Si based layer with a flat upper surface in the trench; and epitaxially growing a SiGe layer with no corner rounding over the Si based layer.

Aspects include the Si based layer including a lattice compliant Si layer. Another aspect includes the Si based layer including a second SiGe layer having a lower Ge concentration than the SiGe layer. Other aspects include forming the lattice compliant Si layer to a thickness of equal to a difference between a depth of the trench and a thickness of the SiGe layer and forming the SiGe layer to a thickness of 10 nm to 60nm.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1C schematically illustrate a process flow for forming of a SiGe layer in a trench and the resulting round corners; and

FIGS. 2A through 2D schematically illustrate a process flow for forming a Si based layer with a flat upper surface in a trench to prevent corner rounding in dual channel devices (e.g., with n-type Si FINs and p-type SiGe FINs), in accordance with an exemplary embodiment.

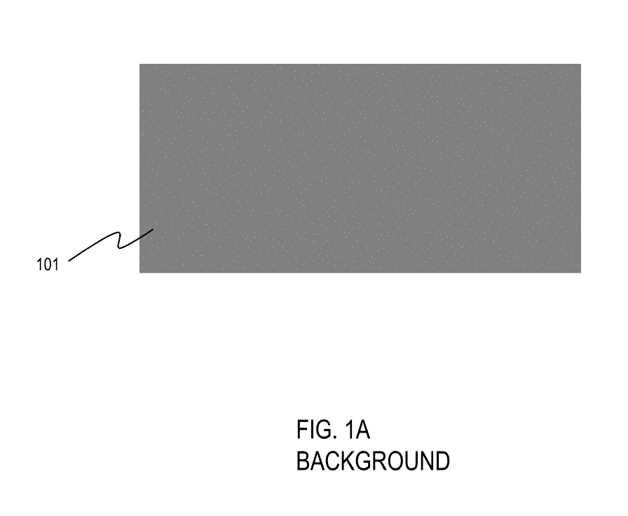

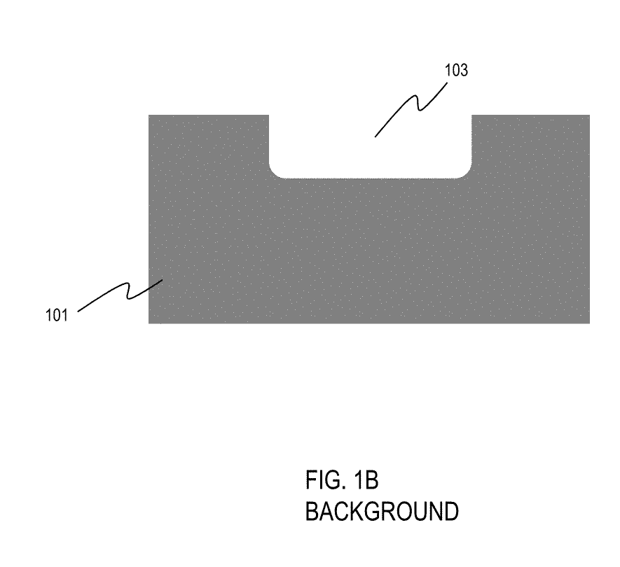

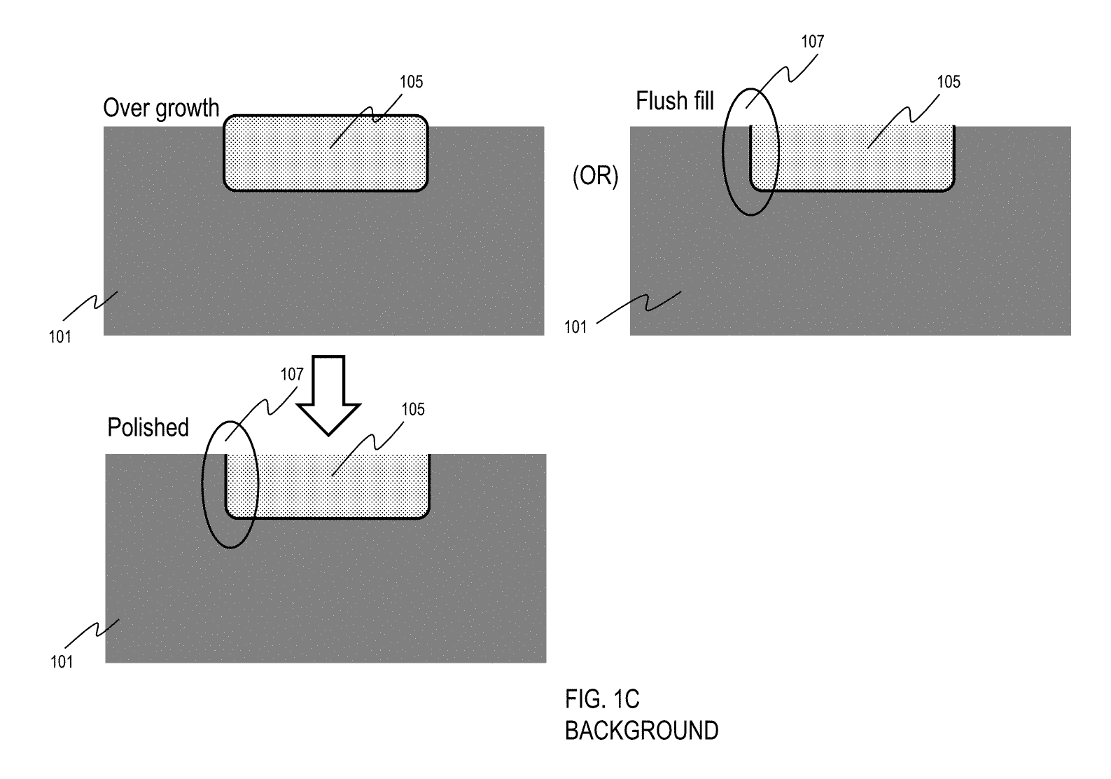

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of corner rounding attendant upon forming a trench in a Si substrate for an alternate channel FINFET. In accordance with embodiments of the present disclosure, a deeper trench is formed and a Si based layer is formed in the trench until a flat upper surface is achieved, prior to epitaxially growing the SiGe layer (over the Si based layer).

Methodology in accordance with embodiments of the present disclosure includes providing a Si substrate and forming a trench in the Si substrate. Then, a Si based layer with a flat upper surface is formed in the trench. Next, a SiGe layer is formed over the Si based layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

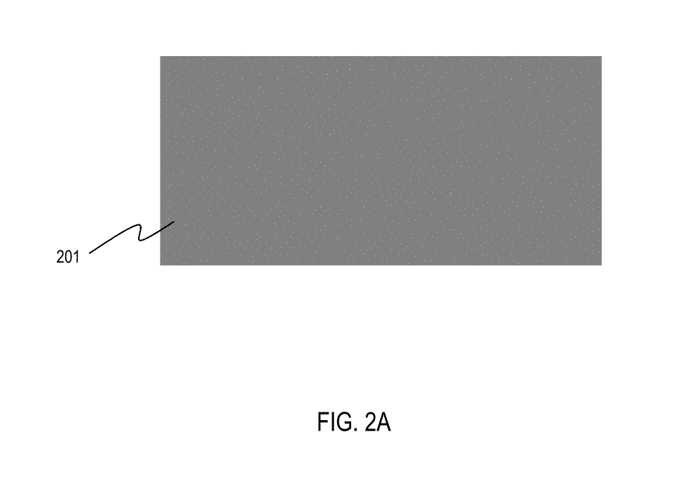

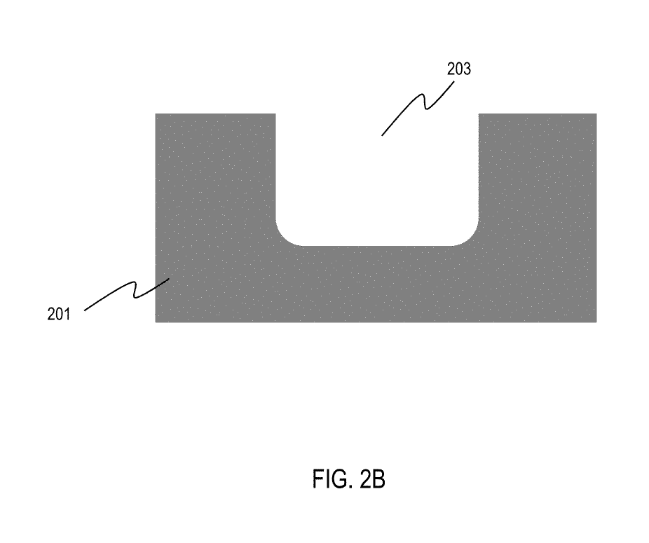

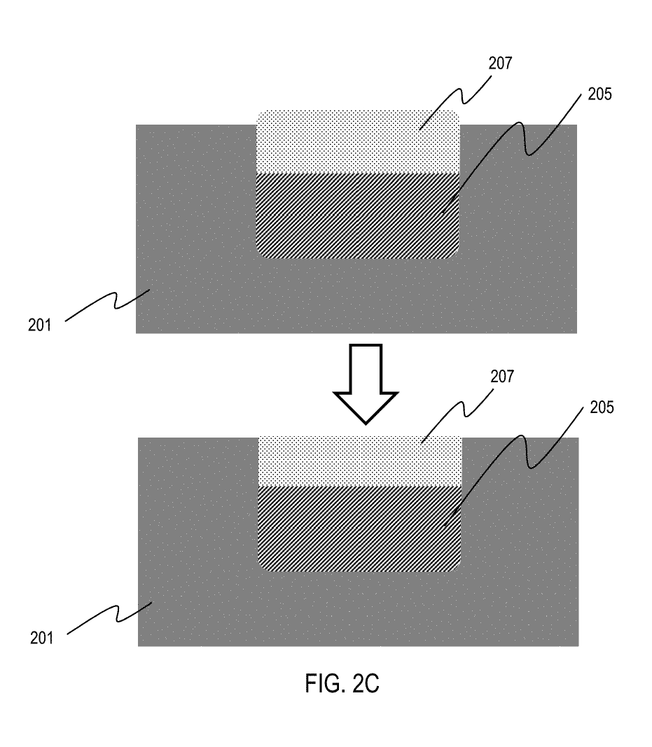

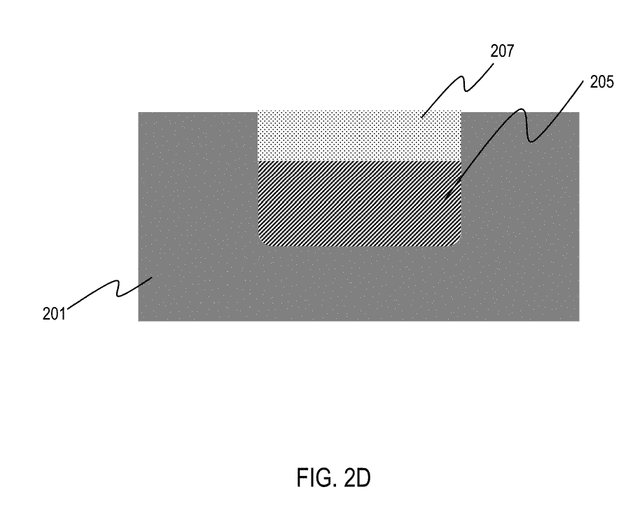

FIGS. 2A through 2D schematically illustrates sequential steps of a method for forming a Si based layer with a flat upper surface in a trench to prevent corner rounding in dual channel devices (e.g., with n-type Si FINs and p-type SiGe FINs), in accordance with an exemplary embodiment. FIG. 2A represents a Si substrate 201. Adverting to FIG. 2B, a trench 203 is formed in the Si substrate 201 by RIE to a depth of 100 nm to 500 nm. The width of the trench may be 100 nm to 5 micrometer (μm), but may vary according to the type of device being formed. For example, for an SRAM, the width may be up to 200 nm, e.g. 150 to 200 nm, and in a logic region, the width may be up to 500 nm. Subsequent to etching, EPI pre-baking is performed on the surfaces of the trench 203 at a temperature of 750° C. to 1200° C. and a pressure of 10 torr to 600 torr for 1 minute to 5 minutes resulting in corner rounding. If, for example, an EPI pre-baking does not generate corner rounding, a Si growth is not required, and a trench having a depth of only 10 nm to 50 nm may be formed, which defines the height of the subsequently formed FINs. A high pre-baking temperature (e.g., temperature close to the melting point) is an ideal pre-baking temperature for blanket deposition of SiGe over Si. However, a lower temperature must be employed for smaller trenches to avoid a significant increase in corner rounding.

In FIG. 2C, a Si based layer 205 with a flat upper surface is formed in the trench 203 to a thickness equal to a difference between the depth of the trench and the intended thickness of the subsequent SiGe layer. The Si based layer 205 may be formed by epitaxially growing a lattice compliant Si layer in the trench 203. Si compliant is defined as the Si based layer 205 having the same inplane lattice constant as the Si substrate 201. Subsequently, a SiGe layer 207 with no corner rounding is formed over the Si based layer 205 to a thickness that, with the Si based layer 205, is greater than (e.g., overfill) the depth of the trench 203. Then, the overgrown SiGe layer 207 is smoothed to the level of the Si substrate 201 by CMP. The SiGe layer 207 is formed on the Si based layer 205 without prebaking. The lattice compliant layer 205 may also be counter doped by ion implantation or in situ doping of an n-type dopant such as arsenic (As) or phosphorus (P) (since the SiGe is for pFET channel) to reduce junction leakage.

Alternatively, as illustrated in FIG. 2D after a trench 203 is formed in the Si substrate 201 by RIE, as in FIG. 2B, a Si based layer 205 with a flat upper surface is formed in the trench 203. Subsequently, a SiGe layer 207 with no corner rounding is formed over the Si based layer 205 to a thickness of 10 nm to 60 nm. The thickness of the SiGe layer 207 plus the Si based layer 205 is equal to the depth of the trench 203 (e.g., flush fill).

Alternatively, if the SiGe layer 207 has a high concentration of germanium (Ge), for example higher than 40%, e.g. 70%, the Si based layer 205 may be a SiGe layer with a low concentration of Ge, for example 5 to 40%. Layers 205 and 207 are chosen so that the second layer maintains stress. Further, the temperature and pressure of the second layer should be less than that of the first layer or within a range where the reflow of the first layer does not occur inside the trench creating a convex trench.

In addition, the Si based layer 205 may include super steep retrograde well (SSRW) type doping. More specifically, SSRW dopants include phosphorous (P) or arsenic (As), with carbon layers that prevent diffusion of the dopants.

The embodiments of the present disclosure can achieve several technical effects, such as an improved device performance, maintaining good gate oxide integrity and a reduced junction leakage. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated FINFET semiconductor devices, particularly for the 14 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
providing a silicon (Si) substrate;
forming a trench in the Si substrate;
epitaxial (EPI) pre-baking surfaces of the trench;
forming a Si based layer with a flat upper surface in the trench; and
forming a silicon germanium (SiGe) layer over the Si based layer.

2. The method according to claim 1, further comprising:
forming the trench by reactive ion etching (RIE).

3. The method according to claim 1, comprising:
forming the Si based layer and the SiGe layer by epitaxially growing a lattice compliant Si layer and the SiGe layer in the trench.

4. The method according to claim 1, comprising forming the Si based layer and the SiGe layer by epitaxially growing first and second SiGe layers, the first SiGe layer having a lower Ge concentration than the second SiGe layer.

5. The method according to claim 1, comprising forming the trench to a depth of 100 nanometer (nm) to 500 nm.

6. The method according to claim 1, comprising:
forming the SiGe layer to a thickness of 10 nm to 60 nm; and
forming the Si based layer to a thickness equal to a difference between a depth of the trench and the thickness of the SiGe layer.

7. The method according to claim 1, further comprising doping the Si based layer with a super steep retrograde well (SSRW) type dopant.

8. (canceled)

9. The method according to claim 1, comprising the EPI pre-baking surfaces of the trench at a temperature of 750° C. to 1200° C. and a pressure of 10 torr to 600 torr for 1 minute to 5 minutes.

10. The method according to claim 3, further comprising:
counter doping the lattice compliant Si layer with an n-type dopant.

11. A device comprising:
a silicon (Si) substrate;
a trench formed in the Si substrate;
a Si based layer with a flat upper surface formed in the trench; and
a silicon germanium (SiGe) layer with no corner rounding formed over the Si based layer.

12. The device according to claim 11, wherein the Si based layer comprises a lattice compliant layer.

13. The device according to claim 11, wherein the Si based layer comprises a second SiGe layer with a Ge concentration lower than the concentration of the SiGe layer.

14. The device according to claim 11, wherein the trench has a depth of 100 nanometer (nm) to 500 nm.

15. The device according to claim 11, wherein:
the SiGe layer has a thickness of 10 nm to 60 nm; and
the Si based layer has a thickness equal to a difference between a depth of the trench and the thickness of the SiGe layer.

16. The device according to claim 11, wherein the Si based layer is doped with a super steep retrograde well (SSRW) type dopant.

17. A method comprising:
providing a silicon (Si) substrate;
etching a trench to a depth of 100 nanometer (nm) to 500 nm in the Si substrate by reactive ion etching (RIE);
epitaxial (EPI) pre-baking surfaces of the trench;
epitaxially growing a Si based layer with a flat upper surface in the trench; and
epitaxially growing a silicon germanium (SiGe) layer with no corner rounding over the Si based layer.

18. The method according to claim 17, wherein the Si based layer comprises a lattice compliant Si layer.

19. The method according to claim 17, wherein the Si based layer comprises a second SiGe layer having a lower Ge concentration than the SiGe layer.

20. The method according to claim 17, comprising forming the SiGe layer to a thickness of 10 nm to 60 nm and forming the lattice compliant Si layer Si based layer to a thickness equal to a difference between a depth of the trench and the thickness of the SiGe layer.
